(19) United States
(12) Patent Application Publication
(10) Pub. No.: US 2004/0248335 A1
(43) Pub. Date: Dec. 9, 2004

(54) Electrode structures for p-type nitride semiconductores and methods of making same

(76) Inventor: Ivan Eliashevich, Maplewood, NJ (US)

Correspondence Address: Scott A. McCollister, Fay, Sharpe, Fagan, Minnich & Mckee, 1100 Superior Avenue, 7th Floor, Cleveland, OH, 44114-2518, US

(21) Appl. No.: 10/468,694

(22) PCT Filed: Jan. 8, 2002
(86) PCT No.: PCT/US02/00310

(30) Foreign Application Priority Data
Jan. 9, 2001 (US) 60260514

(51) Int. Cl. H01L 21/28; H01L 21/3205; H01L 21/00; H01L 21/44

(52) U.S. Cl. 438/47; 438/606; 438/609

(57) ABSTRACT

A semiconductor device includes a semiconductor structure having a p-type nitride semiconductor defining a top surface (17), a buffer layer (20) composed predominantly of a p-type metal oxide semiconductor overlying the top surface (17), and an electrode (26) including one or more metals overlying the buffer layer (20).

### BACKGROUND OF THE INVENTION

The present invention relates to electrode structures for p-type nitride semiconductors such as p-type gallium nitride based semiconductors. As used in this disclosure, the term “III-V semiconductor” refers to a material according to the stoichiometric formula AlaInbGacNxAsyPz. In a perfectly stoichiometric III-V semiconductor, (a+b+c)=(x+y+z)=1.0. The term “nitride semiconductor” refers to III-V semiconductor in which x is 0.5 or more, most typically 0.8 or more. The term “pure nitride semiconductor” refers to a nitride semiconductors in which N constitutes essentially all of the Group V atoms in the semiconductor, and hence x is about 1.0. The term “gallium nitride based semiconductor” as used herein refers to a nitride based semiconductor including gallium. In III-V semiconductors, p-type and n-type conductivity may be imparted by conventional dopants and may also result from the inherent conductivity type of the particular semiconductor material. For example, gallium nitride based semiconductors typically are inherently n-type when undoped. Semiconductors including n-type nitrides may have conventional electron donor dopants such as Si, Ge, S, and O, whereas p-type nitride semiconductors may include conventional electron acceptor dopants such as Mg and Zn.

Nitride semiconductors are used in various semiconductor devices. For example, nitride semiconductors can be used in devices for converting electrical energy to light, such as light emitting diodes (“LED's”) and semiconductor lasers.

Semiconductor devices typically include a semiconductor structure having both p-type and n-type regions and a junction between such regions. The junction between the p-type and n-type material may include directly abutting p-type and n-type layers, or may include one or more intermediate layers which may be of any conductivity type or which may be very thin semi-insulating layers of no distinct conductivity type. The device also includes an electrode in contact with the p-type region and another electrode in contact with the n-type region. The electrodes, in turn, are provided with pads suitable for connection to wires or other conductors which carry current to or from external sources. The pad associated with each electrode may be a part of the electrode, having the same composition and thickness of the electrode, or may be a distinct structure which differs in thickness, composition, or both from the electrode itself. The term “electrode-pad unit” is used in this disclosure to refer to the electrode and pad, regardless of whether the pad is a separate structure or merely a region of the electrode.

For example, in operation of an LED, application of a voltage by an external source through the electrode-pad units causes a current to flow through the device. The current is carried by electrons and electron vacancies or “holes” which move toward the junction, and recombine with one another at the junction. Energy released by electron-hole recombination is emitted as light. As used in this disclosure, the term “light” includes radiation in the infrared and ultraviolet wavelength ranges, as well as the visible range. The wavelength of the light emitted by an LED depends on factors including the composition of the semiconductor materials and the structure of the junction.

It is highly desirable to provide low-resistance, ohmic contact between the electrodes and the semiconductor layers. Electrodes for n-type nitride semiconductors can be formed from various metals such as titanium, aluminum and combinations thereof. Electrodes for p-type nitride semiconductors typically include high work function metals such as Au, Ir, Pt and may also include other metals such as Ni. For example, electrodes for p-type gallium nitride based semiconductors can be formed by depositing layers of nickel and gold directly on the surface of the p-type semiconductor material and annealing the device at an elevated temperature, typically 300 to 900° C.

Some photooptical devices use transparent electrodes. For example, some LED's incorporate transparent electrodes on a top surface of the semiconductor structure. Light emitted at the junction within the LED passes upwardly through the semiconductor structure and out of the device through the transparent electrode. Typically, the top surface of the semiconductor structure is defined by a p-type semiconductor layer. Electrodes with good ohmic contact to p-type gallium nitride based semiconductors and with a substantial degree of transparency to light in the visible and near ultraviolet wavelength range can be formed by depositing a thin layer of nickel and a thin layer of gold on the surface of a p-type semiconductor layer and then annealing the structure at elevated temperature in an atmosphere containing oxygen. The electrode becomes more transparent during the annealing process. The annealing process converts most or all of the nickel to nickel oxide. In the annealed electrode, the nickel oxide is preferentially distributed toward the top surface of the electrode, remote from the semiconductor, and the gold is preferentially distributed toward the bottom of the electrode, near the semiconductor. This occurs even where the nickel is disposed beneath the gold prior to the annealing operation, as by depositing a layer of nickel and then depositing a layer of gold over the nickel layer.

Devices made with electrodes as discussed above on p-type nitride semiconductors tend to degrade or “age” in service. Accordingly, there has been a need prior to the present invention for improved electrode structures which would provide good ohmic contact between the electrode and a p-type nitride semiconductor but which would alleviate the problem of premature aging.

### SUMMARY OF THE INVENTION

One aspect of the present invention provides a semiconductor and electrode structure. The structure according to this aspect of the invention desirably includes a semiconductor structure which has a p-type nitride semiconductor defining a top surface. A buffer layer composed predominantly of a p-type metal oxide semiconductor such as nickel oxide, cobalt oxide, or indium-tin oxide overlies the top surface defined by the nitride semiconductor, and most preferably is contiguous with the nitride semiconductor. One or more electrode layers including one or more metals overlies the buffer layer. Typically, the p-type metal oxide semiconductor has a band gap greater than the band gap of the p-type nitride semiconductor which forms the top surface of the semiconductor structure. In a photooptical device such as an LED, the band gap of the metal oxide semiconductor most preferably is greater than the energy of photons which are emitted by the device or which interact with the device. Preferably, the buffer layer is composed predominantly of nickel oxide, and most preferably the buffer layer consists essentially of nickel oxide.

The electrode desirably includes a high work function metal such as gold, platinum or palladium, and most preferably includes gold. For example, the electrode may include gold and nickel. Some or all of the nickel in the electrode desirably is present as nickel oxide.

A further aspect of the invention provides a method of making an electrode structure for a p-type gallium nitride based semiconductor. A method according to this aspect of the invention desirably includes the steps of providing a buffer layer composed predominantly of a p-type metal oxide semiconductor on the p-type gallium nitride based semiconductor and then depositing one or more metal-containing electrode-forming layers on said buffer layer. Desirably, the step of providing a buffer layer includes depositing a buffer-forming layer of a metal such as nickel and annealing the buffer-forming layer in an oxidizing atmosphere to form the oxide semiconductor of the buffer layer before the electrode-forming layers are applied. Preferably, the method includes the further step of annealing the electrode-forming layer or layers. Where one or more of the electrode-forming layers includes nickel, and where a transparent electrode is desired, the annealing step preferably is performed in an atmosphere containing oxygen. Although the present invention is not limited by any theory of operation, it is believed that the nickel in the electrode-forming layer or layers oxidizes to nickel oxide.

Provision of the buffer layer prior to deposition of the electrode-forming layers is believed to increase the reliability of the resulting semiconductor structure by substantially preventing diffusion of metals such as gold from the electrode-forming layers into the nitride semiconductor during annealing of the electrode-forming layers and during service, although in this respect as well, the present invention is not limited by any theory of operation. A transparent buffer layer does not appreciably block the emitted light. Moreover, the buffer layer provides some additional conductivity in the horizontal direction, along the top surface of the semiconductor layer.

These and other preferred embodiments of the present invention will be provided in more detail below.

### BRIEF DESCRIPTION OF THE DRAWINGS

FIG. 1 shows a semiconductor device including a buffer layer, in accordance with certain preferred embodiments of the present invention.

FIGS. 2-4 show a method of making the semiconductor device of FIG. 1, in accordance with certain preferred embodiments of the present invention.

### DETAILED DESCRIPTION

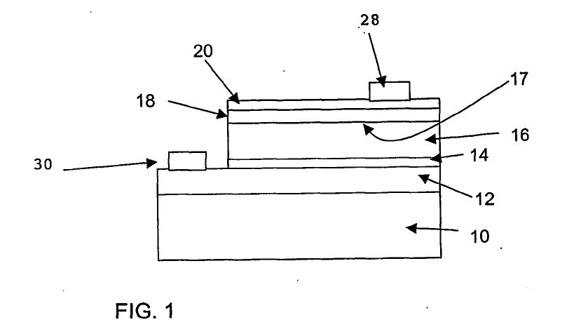

Referring to FIG. 1, an LED in accordance with one preferred embodiment of the invention includes a stacked structure of semiconductor layers on a substrate 10. The stacked structure includes n-type semiconductor material in a lower region 12, p-type nitride semiconductor material in an upper region 16 a junction 14 between these regions. The upper region 16 defines a top surface 17.

Each of regions 12 and 16 can include any number of layers. Merely by way of example, the lower region may incorporate a bottom layer at the interface with substrate 10, whereas the upper region may incorporate a highly doped contact layer defining the top surface 17 to aid in establishing ohmic contact with a top electrode discussed below. The upper region 16 typically is transparent to light at the wavelength which will be emitted by the LED in service. That is, the upper region is formed entirely or principally from materials having a band gap greater than the energy of the photons which will be emitted at the junction. The structure and composition of the various layers incorporated in the stack and the sequence of layers in the stack may be selected according to known principles and techniques to provide the desired emission characteristics.

Lower region 12 and upper region 16 desirably are formed from one or more III-V semiconductors. At least that portion of the upper region 16 which defines top surface 17 is formed from a nitride-based semiconductor, i.e., a III-V semiconductor in which x is 0.5 or more, most typically 0.8 or more, and may be formed from a pure nitride semiconductor. As noted above, the term “gallium nitride based semiconductor” as used herein refers to a nitride based semiconductor including gallium such as GaN, InGaN or AlGaN. Typically, the semiconductor material defining top surface 17 is a gallium nitride based, pure nitride semiconductor, such as GaN, InGaN, AlGaN or AlInGaN. The remainder of the stacked structure may also be formed from the gallium nitride based materials.

The p-type and n-type conductivity of the various layers may be imparted by conventional dopants and may also result from the inherent conductivity type of the particular semiconductor material. For example, gallium nitride based semiconductors typically are inherently n-type even when undoped. n-type nitride semiconductors may include conventional electron donor dopants such as Si, Ge, S, and O, whereas p-type nitride semiconductors may include conventional electron acceptor dopants such as Mg and Zn.

For purposes of clarity, the junction 14 between the n-type lower region 12 and the p-type upper region 16 is shown in FIG. 1 as a discrete layer interposed between regions 12 and 16. In practice, however, the regions 12 and 16 may abut one another so that they define the junction 14 at their mutual border. Alternatively, the junction 14 may include additional layers in the mutually adjacent portions of regions 12 and 16 or between these regions. Thus, the junction may be a simple homojunction; a single heterojunction, a double heterojunction, a single quantum well, a multiple quantum well or any other type of junction structure.

The fabrication processes used to form the stacked structure are also well known. The various layers constituting the stack structure typically are grown on the substrate while the substrate is part of a larger wafer, and the various layers cover the entire wafer. The wafer is later subdivided to form individual pieces or “dies”. Most commonly, the various layers which form the stacked structure are deposited on the substrate in sequence by techniques such as metal organic chemical vapor deposition (“MOCVD”) molecular beam epitaxy and the like.

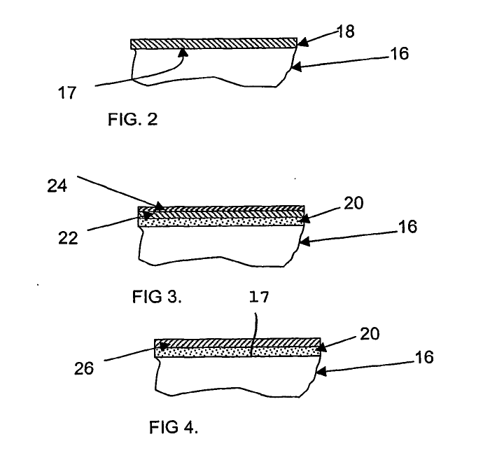

Referring to FIG. 2, following formation of the semiconductor stack structure, and typically while the stack structure is still in wafer form, a buffer-forming layer 18 of a metal such as nickel is deposited on top surface 17, such as by sputter-depositing the buffer forming metal onto the top surface. The buffer-forming layer 18 desirably has a thickness of 10 Å or more, and most typically 25 Å or more. In certain preferred embodiments, buffer-forming layer 18 has a thickness of 10-500 Å, and more preferably a thickness of 25-200 Å. Following deposition, the buffer-forming metal layer 18 is oxidized by annealing the structure with the buffer-forming metal layer in an oxidizing atmosphere, typically at 300-900° C. for a few seconds to a few minutes. Referring to FIG. 3, the annealing process desirably converts the buffer-forming metal entirely or almost entirely to oxide, thereby forming a buffer layer 20 composed predominantly of nickel oxide, and which desirably consists essentially of nickel oxide. As used in this disclosure, a statement that a layer is “composed predominantly of a material” means that the layer contains at least 60% of such material, by mole fraction if not otherwise specified. The time required for complete oxidation of the metal will depend upon the partial pressure of oxygen in the annealing atmosphere and upon the annealing temperature.

After this annealing step, a first electrode forming layer 22 composed predominantly of nickel and desirably consisting essentially of nickel is applied on buffer layer 20, as by sputtering, and a second electrode forming layer 24 composed predominantly of gold is applied on the first electrode forming layer. The order of application of the electrode-forming layers may be reversed. Where a transparent electrode is desired, the electrode-forming layers 22 and 24 together desirably are less than 300 Å thick, and the gold layer 24 should be 150 Å thick or less, more preferably less than 100 Å thick.

Referring to FIG. 4, following application of the electrode-forming layers, the structure is annealed again, in an oxidizing atmosphere so as to form an electrode 26 as a layer overlying and contiguous with the buffer layer 20. Although the electrode 26 is depicted as a uniform layer, the composition of this layer typically is not uniform; it is typically enriched in nickel oxide at the top of the layer, remote from the buffer layer 20, and enriched in gold at its juncture with the buffer layer. For purposes of clarity, the various layers shown in FIG. 4 are depicted with definite boundaries, however, there is a finite compositional gradient at each boundary. Electrode 26 and buffer layer 20 cooperatively provide a low-resistance ohmic contact to the upper region 16 of the semiconductor structure. Thus, there is low resistance to flow of electric current between the electrode 26 and the semiconductor layer.

Referring to FIG. 1, after formation of the electrode, a first pad 28 is formed in electrical contact with the electrode, as by applying successive layers of Ti, Pt and Au. A second electrode-pad unit 30 is formed in contact with the n-type lower region 12 using conventional techniques. For example, a portion of the upper region 16 and junction layer 14 may be etched away to expose a part of the lower region 12. The second electrode-pad unit 30 may be made by depositing layers of Al and Ti which are annealed at an elevated temperature. A layer of Pt can be deposited over the Ti and Al layers, followed by a layer of Au which provides a bondable surface. Some of the steps used to form the second electrode-pad unit 30 may be conducted simultaneously with other steps discussed above.

The embodiment discussed above can be varied in numerous ways. For example, the same buffer layer and contact can be used with semiconductor structures other than LED's. It is not essential that the electrode and buffer layer be transparent. The electrode-forming layers, the buffer layer or both may be thicker where transparency is not desired. Also, oxide semiconductors other than nickel oxide can be used to form the buffer layer. Among the oxide semiconductors which can be employed are cobalt oxide and indium-tin oxide. The oxide semiconductor need not be formed by oxidation of a metal buffer-forming layer in situ. For example, metal oxides can be deposited by sputtering a metal source in an oxidizing atmosphere, or by direct deposition from oxide source by sputtering or e-beam evaporation, or from gas phase by metal-organic chemical vapor deposition (MOCVD). The buffer layer may be doped with a suitable p-type (electron acceptor) dopant to increase the electrical conductivity of the buffer layer. For example, Li, Na and K can serve as acceptors in nickel oxide. However, the dopant should not cause adverse interaction with the nitride semiconductor. Alternatively, p-type oxide may be formed by creating non-stoichiometric Ni-deficient nickel oxide.

As these and other variations and combinations of the features discussed above can be utilized without departing from the present invention, the foregoing description of the preferred embodiments should be taken by way of illustration rather than by way of limitation of the invention as defined by the claims.

1. A method of making a semiconductor structure comprising the steps of:
(a) providing a buffer layer composed predominantly of a p-type oxide semiconductor on a p-type nitride semiconductor; and then
(b) depositing one or more metallic electrode-forming layers on said buffer layer.

2. A method as claimed in claim 1 wherein said p-type nitride semiconductor is a gallium nitride based semiconductor.

3. A method as claimed in claim 1 wherein said buffer layer is composed predominantly of nickel oxide.

4. A method as claimed in claim 3 wherein said buffer layer consists essentially of nickel oxide.

5. A method as claimed in claim 3 wherein said step of providing said buffer layer includes depositing a buffer-forming layer including metallic nickel and then annealing said buffer-forming layer in an atmosphere including oxygen prior to depositing said one or more metallic electrode layers.

6. A method as claimed in claim 5 wherein, prior to said step of annealing said buffer-forming layer, said buffer-forming layer is at least 10 Å thick.

7. A method as claimed in claim 6 wherein, prior to said step of annealing said buffer-forming layer, said buffer-forming layer is between 10 Å and 500 Å thick.

8. A method as claimed in claim 1 wherein said step of depositing one or more electrode-forming layers includes depositing gold.

9. A method as claimed in claim 1 further comprising the step of annealing said one or more electrode-forming layers.

10. A method as claimed in claim 1 wherein said step of depositing one or more electrode-forming layers includes depositing nickel and gold.

11. A method as claimed in claim 10 further comprising the step of annealing said one or more electrode-forming layers in an atmosphere including oxygen.

12. A method as claimed in claim 11 wherein, prior to said step of annealing said one or more electrode-forming layers, said one or more metallic electrode-forming layers have a total thickness less than 300 Å.

13. A method as claimed in claim 1 wherein said electrode and said buffer layer are substantially transparent.

14. A method as claimed in claim 1 wherein said electrode and buffer layer cooperatively provide substantially ohmic contact with said p-type semiconductor layer.

15. A semiconductor device including:
(a) a semiconductor structure including a p-type nitride semiconductor defining a top surface;
(b) a buffer layer composed predominantly of a p-type metal oxide semiconductor overlying said top surface; and
(c) an electrode including one or more metals overlying said buffer layer.

16. A device as claimed in claim 15 wherein said p-type nitride semiconductor defining said top surface is a gallium nitride based semiconductor.

17. A structure as claimed in claim 15 wherein said buffer layer is composed predominantly of nickel oxide.

18. A structure as claimed in claim 17 wherein said buffer layer consists essentially of nickel oxide.

19. A structure as claimed in claim 15 or claim 17 or claim 18 wherein said electrode includes gold.

20. A structure as claimed in claim 19 wherein said buffer layer and said electrode are substantially transparent.

21. A structure as claimed in claim 20 wherein said semiconductor structure is a light emitting diode, and said semiconductor structure is arranged so that light emitted within the diode is transmitted through said buffer layer and said electrode.

22. A structure as claimed in claim 19 wherein said electrode includes gold and nickel.

23. A structure as claimed in claim 19 wherein said electrode includes gold and nickel oxide.

24. A structure as claimed in claim 19 wherein said semiconductor structure is a light emitting diode.
